(19) United States
(12) Patent Application Publication
(10) Pub. No.: US 2026/0136462 A1
(43) Pub. Date: May 14, 2026

(54) PRINTED CIRCUIT BOARD

(71) Applicant: SAMSUNG ELECTRO-MECHANICS CO., LTD., Suwon-si (KR)

(72) Inventors: Jung Soo KIM, Suwon-si (KR); Sung Chul CHOI, Suwon-si (KR); Na Ri JIN, Suwon-si (KR); Saet Byeol YOUN, Suwon-si (KR)

(73) Assignee: SAMSUNG ELECTRO-MECHANICS CO., LTD., Suwon-si (KR)

(21) Appl. No.: 19/317,627

(22) Filed: Sep. 3, 2025

(30) Foreign Application Priority Data
Nov. 14, 2024 (KR) 10-2024-0162010

(51) Int. Cl. H05K 1/11; H05K 1/03

(52) U.S. Cl. CPC H05K 1/115; H05K 1/0366; H05K 1/0373; H05K 2201/0209

(57) ABSTRACT

A printed circuit board includes an insulating layer comprising a first insulating material having a first opening and a second insulating material laminated on one surface of the first insulating material. The second insulating material fills at least a portion of the first opening and comprises a material different from that of the first insulating material. A wiring pattern is disposed on one surface of the first insulating material and is embedded in the second insulating material such that one surface of the wiring pattern is exposed from one surface of the second insulating material. A via pattern is spaced apart from the first insulating material in the first opening and is embedded in the second insulating material such that one surface of the via pattern is exposed from the one surface of the second insulating material.

### CROSS-REFERENCE TO RELATED APPLICATION(S)

This application claims the benefit of priority to Korean Patent Application No. 10-2024-0162010 filed on Nov. 14, 2024 with the Korean Intellectual Property Office, the disclosure of which is incorporated herein by reference in its entirety.

### TECHNICAL FIELD

The present disclosure relates to a printed circuit board.

In the case of substrates included in high-spec products such as 2.5D package substrates, and package substrates for servers, high-frequency characteristics, microcircuit formation, and warpage control have been required. Formation of a buried circuit on a substrate may be considered to form a microcircuit. For example, a groove may be formed in an insulating layer using laser processing without a stopper layer and then filled with plating to form a buried circuit. However, in this case, there may be limitations in controlling laser processing thickness. Accordingly, a variation in circuit thickness may occur. In this case, it may be difficult to implement high-frequency characteristics. In addition, when a processing depth increases, a buried circuit may be electrically connected to a lower circuit or pad. In addition, migration reliability may be reduced. In addition, there may be difficulties in warpage control. In addition, there may be limitations in reducing a diameter of a via.

### SUMMARY

An aspect of the present disclosure is to provide a printed circuit board capable of easily forming a microcircuit, improving transmission characteristics, reducing warpage, and reducing a diameter of a via, when a buried circuit is formed.

A hybrid-type insulating layer having at least a two-layer structure may be formed using different insulating materials, and a buried circuit may be formed on the hybrid-type insulating layer using laser processing.

According to an aspect of the present disclosure, there is provided a printed circuit board including an insulating layer including a first insulating material having a first opening, and a second insulating material laminated on one surface of the first insulating material, the second insulating material filling at least a portion of the first opening, the second insulating material including a material different from that of the first insulating material, a wiring pattern disposed on one surface of the first insulating material, the wiring pattern embedded in the second insulating material such that one surface thereof is exposed from one surface of the second insulating material, and a via pattern spaced apart from the first insulating material in the first opening, the via pattern embedded in the second insulating material such that one surface thereof is exposed from the one surface of the second insulating material.

According to another aspect of the present disclosure, there is provided a printed circuit board including a first insulating layer, a first pad pattern disposed on the first insulating layer, a second insulating layer disposed on the first insulating layer, the second insulating layer covering at least a portion of the first pad pattern, the second insulating layer having a first opening exposing at least another portion of the first pad pattern, a wiring pattern disposed on the second insulating layer, a third insulating layer disposed on the second insulating layer, the third insulating layer covering at least a portion of the wiring pattern, the third insulating layer filling at least a portion of the first opening, and a via pattern connected to at least an open portion of the first pad pattern, the via pattern spaced apart from the second insulating layer in the first opening, the via pattern having a side surface having at least a portion covered by the third insulating layer. Each of an upper surface of the wiring pattern and an upper surface of the via pattern may be exposed from an upper surface of the third insulating layer. The second and third insulating layers may include different insulating materials.

According to example embodiments of the present disclosure, a printed circuit board may easily form a microcircuit, improve transmission characteristics, reduce warpage, and reduce a diameter of a via, when a buried circuit is formed.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic cross-sectional view of an example of a printed circuit board;

FIGS. 3 and 4 are schematic process diagrams of an example of manufacturing the printed circuit board of FIG. 2;

FIG. 5 is a schematic cross-sectional view of a modification of the printed circuit board of FIG. 2;

FIG. 6 is a schematic cross-sectional view of another example of a printed circuit board;

FIGS. 7 and 8 are schematic process diagrams of an example of manufacturing the printed circuit board of FIG. 6; and

FIG. 9 is a schematic cross-sectional view of a modification of the printed circuit board of FIG. 6.

### DETAILED DESCRIPTION

Hereinafter, example embodiments of the present disclosure are described with reference to the accompanying drawings. The shapes and sizes of components in the drawings may be exaggerated or reduced for clearer description.

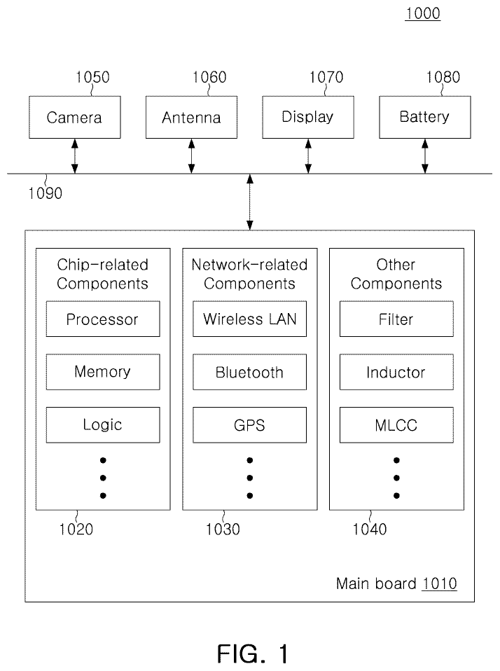

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+ (HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are not limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

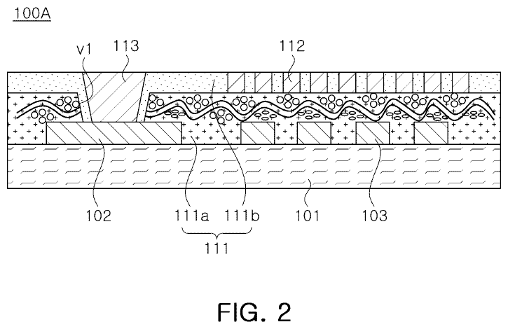

FIG. 2 is a schematic cross-sectional view of an example of a printed circuit board.

Referring to the drawings, a printed circuit board 100A according to an example may include an insulating layer 111 including a first insulating material 111a having a first opening v1 and a second insulating material 111b laminated on one surface of the first insulating material 111a, the second insulating material 111b filling at least a portion of the first opening v1, a wiring pattern 112 disposed on one surface of the first insulating material 111a, the wiring pattern 112 embedded in the second insulating material 111b such that one surface thereof is exposed from one surface of the second insulating material 111b, and a via pattern 113 spaced apart from the first insulating material 111a in the first opening v1, the via pattern 113 embedded in the second insulating material 111b such that one surface thereof is exposed from the one surface of the second insulating material 111b. Each of the wiring pattern 112 and the via pattern 113 may be embedded in the second insulating material 111b in the form of being substantially coplanar with the one surface of the second insulating material 111b. However, each of the wiring pattern 112 and the via pattern 113 may be embedded in the second insulating material 111b in a manner such that each of the wiring pattern 112 and the via pattern 113 is recessed inward from the one surface of the second insulating material 111b, as necessary. The first and second insulating materials 111a and 111b may include different materials. For example, the insulating layer 111 may have a hybrid-type lamination structure.

As described, the printed circuit board 100A according to an example may include a wiring pattern 112 embedded in one side of the insulating layer 111, and thus a microcircuit may be easily implemented. In this case, the insulating layer 111 may include a structure in which the first and second insulating materials 111a and 111b including different materials are laminated. For example, the first insulating material 111a may include a glass fiber (glass cloth and/or glass fabric), but the second insulating material 111b may not include a glass fiber. In this case, the second insulating material 111b may not include a glass fiber. Thus, a pattern groove for forming a buried circuit may be easily formed using laser processing. In addition, the glass fiber may have relatively poor laser absorption and high thermal decomposition temperature, and thus may have a relatively high amount of energy for processing. Thus, the glass fiber included in the first insulating material 111a may serve as a stopper layer for laser processing, thereby preventing the occurrence of a variation in thickness of the microcircuit. As a result, transmission characteristics may be improved. In addition, a processing depth may be controlled, thereby preventing the buried circuit from being electrically connected to a lower circuit or pad. In addition, migration reliability may be improved. In addition, warpage may be reduced through the glass fiber.

In addition, in the printed circuit board 100A according to an example, the first opening v1 may be formed in the first insulating material 111a using via processing, and the first opening v1 may be filled with the second insulating material 111b. Then, a via hole passing through the second insulating material 111b may be processed on the first opening v1, and the via hole may be filled with plating. As a result, the via pattern 113 spaced apart from the first insulating material 111a in the first opening v1, the via pattern 113 having a side surface surrounded by the second insulating material 111b may be formed. In this case, the via pattern 113 having a reduced diameter may be stably formed regardless of the glass fiber included in the first insulating material 111a protrudes to a wall surface of the via hole. The via pattern 113 may have a landless structure. The second insulating material 111b may not have a glass fiber or the like serving as a stopper layer for land formation. In this case, laser processing for land formation may rather complicate a process.

A thickness of the first insulating material 111a may be greater than that of the second insulating material 111b. For example, the second insulating material 111b may be a layer for forming the wiring pattern 112, a buried circuit. Thus, the second insulating material 111b may be formed to be relatively thinner than the first insulating material 111a. From a similar viewpoint, the first insulating material 111a may be an insulating material including an insulating resin, an inorganic filler, and a glass fiber, for example, a prepreg, and the second insulating material 111b may include an insulating material including an insulating resin and an inorganic filler and not including a glass fiber, for example, an Ajinomoto build-up film (ABF), but the present disclosure is not limited thereto.

Referring to the drawings, the printed circuit board 100A according to an example may further include a core layer 101, a first pad pattern 102 disposed on one surface of the core layer 101, and a core wiring pattern 103 disposed on the one surface of the core layer 101. Each of the insulating layer 111, the wiring pattern 112, and the via pattern 113 may be disposed on the one surface of the core layer 101. At least a portion of the first pad pattern 102 may be covered with the first insulating material 111a, and at least another portion of the first pad pattern 102 may be exposed from the first insulating material 111a through the first opening v1. The via pattern 113 may be connected to the at least another exposed portion of the first pad pattern 102. For example, the first pad pattern 102 may serve as a stopper layer of a double via hole for forming the via pattern 113. The core wiring pattern 103 may be embedded in the first insulating material 111a. In this case, the wiring pattern 112 including the microcircuit may be disposed at a density higher than that of the core wiring pattern 103. For example, the wirings may have smaller lines, spaces, pitches, or the like.

The core layer 101, the first insulating material 111a, and the second insulating material 111b may be a first insulating layer 101, a second insulating layer 111a, and a third insulating layer 111b, respectively. In addition, the core wiring pattern 103 may be a lower wiring pattern 103. For example, a structure may not be limited to the term “core.” For example, the printed circuit board 100A according to an example may include a first insulating layer 101, a first pad pattern 102 and a lower wiring pattern 103 disposed on the first insulating layer 101, a second insulating layer 111a disposed on the first insulating layer 101, the second insulating layer 111a covering at least a portion of each of the first pad pattern 102 and the lower wiring pattern 103, the second insulating layer 111a having a first opening v1 for opening at least another portion of the first pad pattern 102, a wiring pattern 112 disposed on the second insulating layer 111a, a third insulating layer 111b disposed on the second insulating layer 111a, the third insulating layer 111b covering at least a portion of the wiring pattern 112, the third insulating layer 111b filling at least a portion of the first opening v1, and a via pattern 113 connected to at least an open portion of the first pad pattern 102, the via pattern 113 spaced apart from the second insulating layer 111a in the first opening v1, the via pattern 113 having a side surface having at least a portion covered by the third insulating layer 111b. In the direction illustrated in the drawings, each of an upper surface of the wiring pattern 112 and an upper surface of the via pattern 113 may be exposed from an upper surface of the third insulating layer 111b. The second and third insulating layers 111b and 111c may include different insulating materials.

Hereinafter, components of the printed circuit board 100A according to an example will be described in more detail with reference to the drawings.

The core layer 101 or the first insulating layer 101 may include an organic insulating material. Here, the organic insulating material may include a thermosetting resin such as an epoxy resin, a thermoplastic resin such as polyimide, or an inorganic filler and/or a glass fiber together with the above-described insulating resins. For example, the core layer 101 or the first insulating layer 101 may be a copper clad laminate (CCL) or an unclad CCL, but the present disclosure is not limited thereto. The core layer 101 or the first insulating layer 101 may include other insulating materials. The core layer 101 or the first insulating layer 101 may include an inorganic insulating material such as glass, silicon or ceramic, as necessary. In addition, the core layer 101 or the first insulating layer 101 may include a metal core.

The first pad pattern 102 may include a metal. The metal may include copper (Cu), aluminum (Al), silver (Ag), tin (Sn), gold (Au), nickel (Ni), lead (Pb), titanium (Ti), and/or alloys thereof. For example, the first pad pattern 102 may include chemical copper, formed using electroless plating, as a seed layer, and may include electrolytic copper, formed using electrolytic plating based thereon, as a pattern plating layer. However, the present disclosure is not limited thereto, and the first pad pattern 102 may include a titanium (Ti) layer and a copper (Cu) layer, formed using sputtering, as a seed layer. The first pad pattern 102 may perform various functions depending on a design thereof. For example, the first pad pattern 102 may include a signal transmission pad, a power transmission pad, a ground transmission pad, and the like.

The core wiring pattern 103 or the lower wiring pattern 130 may include a metal. The metal may include copper (Cu), aluminum (Al), silver (Ag), tin (Sn), gold (Au), nickel (Ni), lead (Pb), titanium (Ti), and/or alloys thereof. For example, the core wiring pattern 103 or the lower wiring pattern 130 may include chemical copper, formed using electroless plating, as a seed layer, and may include electrolytic copper, formed using electrolytic plating based thereon, as a pattern plating layer. However, the present disclosure is not limited thereto. The core wiring pattern 103 or the lower wiring pattern 130 may include a titanium (Ti) layer and a copper (Cu) layer, formed using sputtering, as a seed layer. The core wiring pattern 103 or the lower wiring pattern 130 may perform various functions depending on a design thereof. For example, the core wiring pattern 103 or the lower wiring pattern 130 may include a signal transmission wiring, a power transmission wiring, a ground transmission wiring, and the like. The above-described wirings may have various pattern shapes such as a line, a trace, and a plane.

Each of the first and second insulating materials 111a and 111b or the second and third insulating layers 111a and 111b may include an organic insulating material. Here, the organic insulating material may include a thermosetting resin such as an epoxy resin, a thermoplastic resin such as polyimide, or an inorganic filler, an organic filler, and/or a glass fiber together with the above-described insulating resins. For example, the first insulating material 111a or the second insulating layer 111a may include an insulating resin and a prepreg including an inorganic filler and a glass fiber, and the second insulating material 111b or the third insulating layer 111b may include an ABF including an insulating resin and an inorganic filler, but the present disclosure is not limited thereto. For example, the first insulating material 111a or the second insulating layer 111a may include another organic insulating material including a core material such as a glass fiber, and the second insulating material 111b or the third insulating layer 111b may include another organic insulating material not including a core material such as a glass fiber.

The wiring pattern 112 may include a metal. The metal may include copper (Cu), aluminum (Al), silver (Ag), tin (Sn), gold (Au), nickel (Ni), lead (Pb), titanium (Ti), and/or alloys thereof. For example, the wiring pattern 112 may include chemical copper, formed using electroless plating, as a seed layer, and may include electrolytic copper, formed using electrolytic plating based thereon, as a pattern plating layer. However, the present disclosure is not limited thereto. The wiring pattern 112 may include a titanium (Ti) layer and a copper (Cu) layer, formed using sputtering, as a seed layer. The wiring pattern 112 may perform various functions depending on a design thereof. For example, the wiring pattern 112 may include a signal transmission wiring and the like. The wirings may have various pattern shapes such as a line and a trace. Other types of wiring patterns for power or ground excluding the wiring pattern 112, a microcircuit, may be further formed on a level, substantially the same as that of the wiring pattern 112, as necessary.

The via pattern 113 may include a metal. The metal may include copper (Cu), aluminum (Al), silver (Ag), tin (Sn), gold (Au), nickel (Ni), lead (Pb), titanium (Ti), and/or alloys thereof. For example, the via pattern 113 may include chemical copper, formed using electroless plating, as a seed layer, and may include electrolytic copper, formed using electrolytic plating based thereon, as a pattern plating layer. However, the present disclosure is not limited thereto. The via pattern 113 may include a titanium (Ti) layer and a copper (Cu) layer, formed using sputtering, as a seed layer. The via pattern 113 may perform various functions depending on a design thereof. For example, the via pattern 113 may include a signal transmission via, a power transmission via, a ground transmission via, and the like. In the drawings, the via pattern 113 may have a tapered shape having an upper end having a width, greater than a width of a lower end thereof, in cross-section. In addition, the via pattern 113 may have a fill-plated via structure. In addition, the via pattern 113 may have a landless via structure.

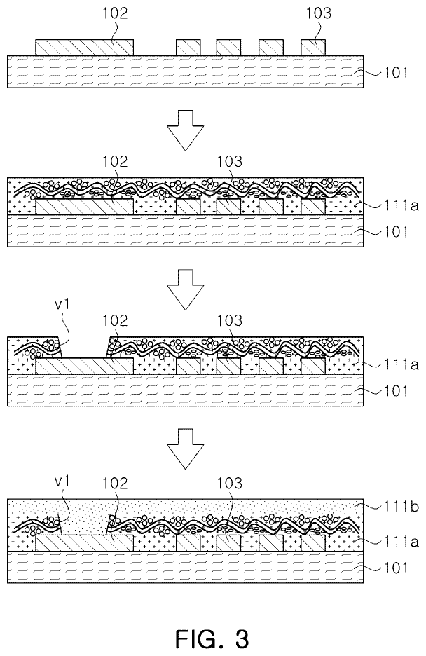

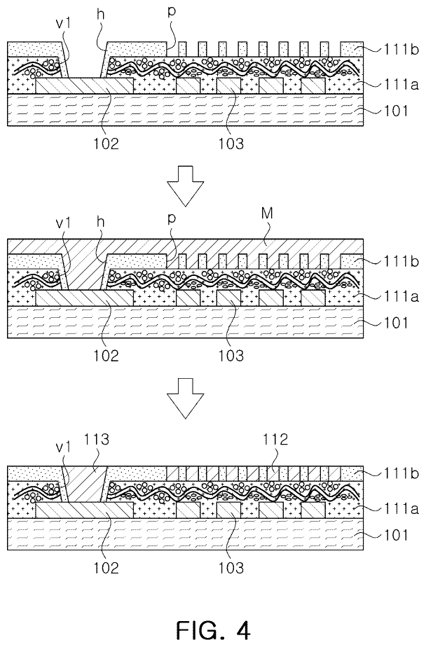

FIGS. 3 and 4 are schematic process diagrams of an example of a method for manufacturing the printed circuit board of FIG. 2.

Referring to the drawings, a first pad pattern 102 and a core wiring pattern 103 may be formed on a core layer 101. The first pad pattern 102 and the core wiring pattern 103 may be formed using a circuit formation process such as a semi-additive process (SAP), a modified semi-additive process (MSAP), tenting (TT), or the like. Subsequently, a first insulating material 111a, covering the first pad pattern 102 and the core wiring pattern 103, may be formed on the core layer 101. The first insulating material 111a may be formed by laminating an insulating material including a glass fiber, for example, a prepreg. Subsequently, a first opening v1, exposing at least a portion of the first pad pattern 102, may be formed in the first insulating material 111a. The first opening v1 may be formed using CO₂ or UV laser processing. Subsequently, a second insulating material 111b, filling the first opening v1, may be formed on the first insulating material 111a. The second insulating material 111b may be formed by laminating an insulating material not including a glass fiber, for example, an ABF.

Subsequently, a via hole h, re-exposing at least a portion of the first pad pattern 102, may be formed in the second insulating material 111b filling the first opening v1. In addition, a pattern groove p for forming a wiring pattern 112 may be formed in the second insulating material 111b. The via hole h may be formed using CO₂ or UV laser processing. The pattern groove p may be formed using excimer laser processing. Both the via hole h and the pattern groove p may be formed using excimer laser processing. In this case, processing of a pattern groove for forming a land in the via hole h may be omitted. This may be because, in the absence of a stopper layer, over-processing may occur. Subsequently, a plating layer M, filling the via hole h and the pattern groove p, may be formed using plating. Plating may be performed using sputtering, electroless plating, and/or electrolytic plating. Subsequently, the plating layer M on the second insulating material 111b may be polished and removed using chemical mechanical polishing (CMP) or a belt sander. As a result, a wiring pattern 112 and a via pattern 113 may be formed. During the polishing process, respective surfaces of the second insulating material 111b, the wiring pattern 112, and the via pattern 113 may become substantially coplanar with each other, but the present disclosure is not limited thereto. A portion of each of the wiring pattern 112 and the via pattern 113 may be removed, whereby one surface of each of the wiring pattern 112 and the via pattern 113 may be recessed relatively inward.

The above-described printed circuit board 100A according to an example may be manufactured through a series of processes, and other descriptions may be the same as those described above. The core layer 101, the first insulating material 111a, and the second insulating material 111b may be a first insulating layer 101, a second insulating layer 111a, and a third insulating layer 111b, respectively. In addition, the core wiring pattern 103 may be a lower wiring pattern 103. For example, a process may not be limited to the term “core.”

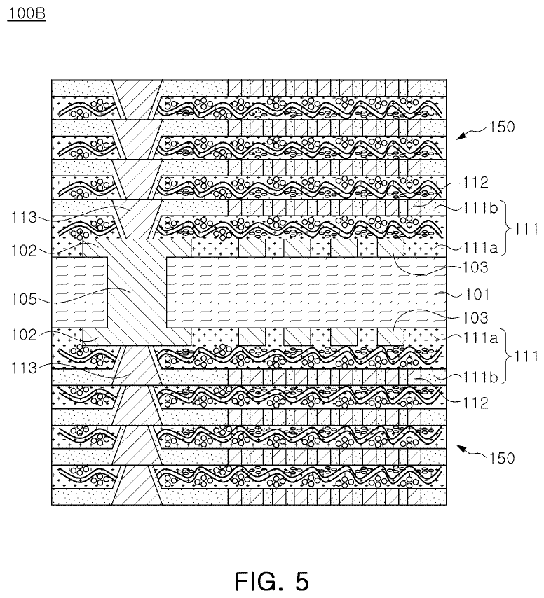

FIG. 5 is a schematic cross-sectional view of a modification of the printed circuit board of FIG. 2.

Referring to the drawings, a printed circuit board 100B according to a modification may include a core layer 101, a first pad pattern 102 disposed on each of one surface and the other surface of the core layer 101 opposing each other, a core wiring pattern 103 disposed on each of the one surface and the other surface of the core layer 101 opposing each other, a through-via 105 connecting the first pad patterns 102, respectively disposed on the one surface and the other surface of the core layer 101, to each other, and a plurality of build-up layers 150 respectively disposed on the one surface and the other surface of the core layer 101. In this case, the plurality of build-up layers 150 may include an insulating layer 111 including first and second insulating materials 111a and 111b described in connection with the above-described printed circuit board 100A according to an example, a wiring pattern 112 and a via pattern 113. On the one surface of the core layer 101 or the other surface of the core layer 101, the via patterns 113 respectively included in two build-up layers 150 adjacent to each other in a thickness direction, among the plurality of build-up layers 150, may be directly connected to each other. For example, a pad or land may be omitted therebetween. Components on both sides of the core layer 101 may not need to be symmetrical to each other. For example, the core wiring patterns 103, disposed on the one surface and the other surface of the core layer 101 opposing each other, may have the same design region or different design regions. In addition, the plurality of build-up layers 150 may also have the same design region or different design regions.

As described, the printed circuit board 100B according to a modification may be a multilayer core substrate including the plurality of build-up layers 150 formed on both sides of the core layer 101. Accordingly, the printed circuit board 100B according to a modification may be easily applied to a large-area package substrate or the like. The plurality of build-up layers 150 may also be formed only on the one surface or the other surface of the core layer 101, as necessary. In this case, the printed circuit board 100B according to a modification may be easily applied to an interposer substrate or the like.

A thickness of the core layer 101 may be greater than that of each of the plurality of build-up layers 150. For example, the thickness of the core layer 101 may be greater than that of the insulating layer 111 of each of the plurality of build-up layers 150. For example, the thickness of the core layer 101 may be greater than that of each of the first and second insulating materials 111a and 111b, included in the insulating layer 111 of each of the plurality of build-up layers 150. For example, the core layer 101 may be a CCL, an unclad CCL, or the like, but the present disclosure is not limited thereto. The core layer 101 may include other insulating materials. The core layer 101 may include an inorganic insulating material such as glass, silicon, or ceramic, as necessary. In addition, the core layer 101 may include a metal core.

The through-via 105 may include a metal. The metal may include copper (Cu), aluminum (Al), silver (Ag), tin (Sn), gold (Au), nickel (Ni), lead (Pb), titanium (Ti), and/or alloys thereof. For example, the through-via 105 may include chemical copper, formed using electroless plating, as a seed layer, and may include electrolytic copper, formed using electrolytic plating based thereon, as a pattern plating layer. However, the present disclosure is not limited thereto. The through-via 105 may include a titanium (Ti) layer, a copper (Cu) layer, or the like formed by sputtering as a seed layer. The through-via 105 may perform various functions depending on a design thereof. For example, the through-via 105 may include a signal transmission via, a power transmission via, a ground transmission via, and the like. The through-via 105 may have a cylindrical shape, but the present disclosure is not limited thereto. The through-via 105 may have an hourglass shape or the like. The through-via 105 may have a fill-plated via structure, but the present disclosure is not limited thereto. The through-via 105 may have a via structure filled with a filler after being conformally plated.

Other descriptions may be substantially the same as those described in connection with the printed circuit board 100A according to an example and the example of manufacturing the same.

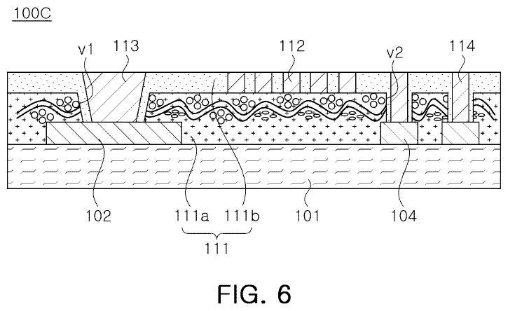

FIG. 6 is a schematic cross-sectional view of another example of a printed circuit board.

Referring to the drawings, as compared to the above-described printed circuit board 100A according to an example, in a printed circuit board 100C according to another example, a first insulating material 111a may further have a second opening v2, a second insulating material 111b may further fill at least a portion of the second opening v2, and a metal pattern 114 spaced apart from the first insulating material 111a in the second opening v2, the metal pattern 114 having one surface exposed from one surface of the second insulating material 111b, may be further embedded in the second insulating material 111b. In addition, a second pad pattern 104, having at least a portion covered with the first insulating material 111a and at least another portion exposed from the first insulating material 111a through the second opening v2, may be further disposed on one surface of the core layer 101. The metal pattern 114 may be connected to the at least another exposed portion of the second pad pattern 104. A thickness of the metal pattern 114 may be greater than that of the wiring pattern 112. The wiring pattern 112 may include a signal transmission line, and the metal pattern 114 may include a power transmission line. The core wiring pattern 103 may be omitted, but may not be omitted, as necessary.

As described, the printed circuit board 100B according to another example may further include a metal pattern 114 disposed in a shape similar to that of the via pattern 113. In this case, the thickness of the metal pattern 114 may be relatively greater than that of the wiring pattern 112, and thus may be easily used when a large thickness, such as a power signal line, is required. In addition, the printed circuit board 100B according to another example may have a structure substantially the same as that of the above-described printed circuit board 100A according to an example, and thus may also have technical effects substantially the same as the above-described technical effects.

The core layer 101, the first insulating material 111a, and the second insulating material 111b may be a first insulating layer 101, a second insulating layer 111a, and a third insulating layer 111b, respectively. For example, a structure may not be limited to the term “core.” For example, the printed circuit board 100B according to another example may include a first insulating layer 101, a first pad pattern 102 and a second pad pattern 104 disposed on the first insulating layer 101, a second insulating layer 111a disposed on the first insulating layer 101, the second insulating layer 111a covering at least a portion of each of the first pad pattern 102 and the second pad pattern 104, the second insulating layer 111a having a first opening v1 for opening at least another portion of the first pad pattern 102 and a second opening v2 for opening at least another portion of the second pad pattern 104, a wiring pattern 112 disposed on the second insulating layer 111a, a third insulating layer 111b disposed on the second insulating layer 111a, the third insulating layer 111b covering at least a portion of the wiring pattern 112, the third insulating layer 111b filling at least a portion of the first opening v1, a via pattern 113 connected to at least an open portion of the first pad pattern 102, the via pattern 113 spaced apart from the second insulating layer 111a in the first opening v1, the via pattern 113 having a side surface having at least a portion covered by the third insulating layer 111b, and a metal pattern 114 connected to at least an open portion of the second pad pattern 104, the metal pattern 114 spaced apart from the second insulating layer 111a in the second opening v2, the metal pattern 114 having a side surface having at least a portion covered by the third insulating layer 111b. In the direction illustrated in the drawings, each of an upper surface of the wiring pattern 112, an upper surface of the via pattern 113, and an upper surface of the metal pattern 114 may be exposed from an upper surface of the third insulating layer 111b. The second and third insulating layers 111b and 111c may include different insulating materials.

Hereinafter, components of the printed circuit board 100C according to another example will be described in more detail with reference to the drawings.

The second pad pattern 104 may include a metal. The metal may include copper (Cu), aluminum (Al), silver (Ag), tin (Sn), gold (Au), nickel (Ni), lead (Pb), titanium (Ti), and/or alloys thereof. For example, the second pad pattern 104 may include chemical copper, formed using electroless plating, as a seed layer, and may include a titanium (Ti) layer and a copper (Cu) layer, formed using sputtering, as a seed layer. In addition, the second pad pattern 104 may include electrolytic copper, formed using electrolytic plating based on the seed layer, as a pattern plating layer. The second pad pattern 104 may perform various functions depending on a design thereof. For example, the second pad pattern 104 may include a power transmission pad or the like.

The metal pattern 114 may include a metal. The metal may include copper (Cu), aluminum (Al), silver (Ag), tin (Sn), gold (Au), nickel (Ni), lead (Pb), titanium (Ti), and/or alloys thereof. For example, the metal pattern 114 may include chemical copper, formed using electroless plating, as a seed layer, and may include a titanium (Ti) layer and a copper (Cu) layer, formed using sputtering, as a seed layer. In addition, the metal pattern 114 may include electrolytic copper, formed using electrolytic plating based on the seed layer, as a pattern plating layer. The metal pattern 114 may perform various functions depending on a design thereof. For example, the metal pattern 114 may include a power transmission pad or the like. The above-described wirings may have various pattern shapes such as a line and a trace. In the drawings, the metal pattern 114 may have a columnar shape on a multi-faceted surface, but the present disclosure is not limited thereto.

Other descriptions may be substantially the same as those described in connection with the above-described printed circuit board 100A according to an example and the example of manufacturing the same.

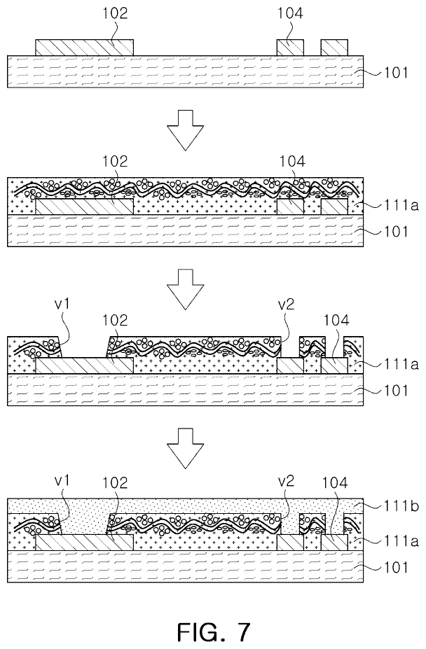

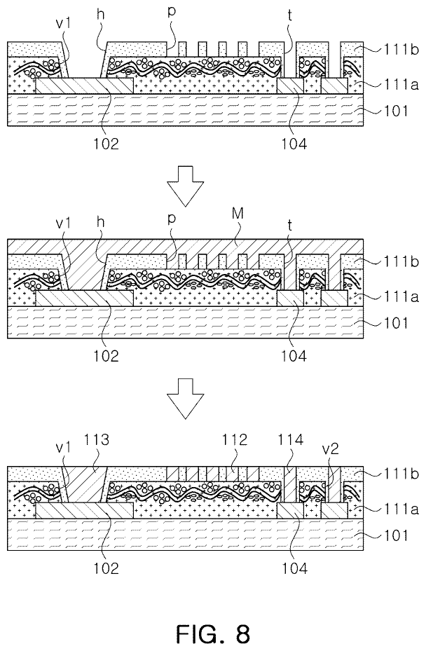

FIGS. 7 and 8 are schematic process diagrams of an example of manufacturing the printed circuit board of FIG. 6.

Referring to the drawings, first and second pad patterns 102 and 104 may be formed on a core layer 101. The first and second pad patterns 102 and 104 may be formed using a circuit formation process such as an SAP, an MSAP, TT, or the like. Subsequently, a first insulating material 111a, covering the first and second pad patterns 102 and 104, may be formed on the core layer 101. The first insulating material 111a may be formed by laminating an insulating material including a glass fiber, for example, a prepreg. Subsequently, a first opening v1 and a second opening v2, respectively exposing at least portions of the first and second pad patterns 102 and 104, may be formed in the first insulating material 111a. The first opening v1 and the second opening v2 may be formed using CO₂ or UV laser processing. Subsequently, a second insulating material 111b, filling the first opening v1 and the second opening v2, may be formed on the first insulating material 111a. The second insulating material 111b may be formed by laminating an insulating material not including a glass fiber, for example, an ABF.

Subsequently, a via hole h and a trench t, respectively exposing at least portions of the first and second pad patterns 102 and 104, may be formed in the second insulating material 111b filling the first and second openings v1 and v2. In addition, a pattern groove p for forming a wiring pattern 112 may be formed in the second insulating material 111b. The via hole h and the trench t may be formed using CO₂ or UV laser processing. The pattern groove p may be formed using excimer laser processing. All of the via hole h, the trench t, and the pattern groove p may be formed using excimer laser processing. In this case, processing of a pattern groove for forming a land in the via hole h may be omitted. This may be because, in the absence of a stopper layer, over-processing may occur. Subsequently, a plating layer M filling the via hole h, the trench t, and the pattern groove p may be formed using plating. Plating may be performed using sputtering, electroless plating and/or electrolytic plating. Subsequently, the plating layer M on the second insulating material 111b may be polished and removed using chemical mechanical polishing (CMP), a belt sander, or the like. As a result, the wiring pattern 112, the via pattern 113, and the metal pattern 114 may be formed. During the polishing process, respective surfaces of the second insulating material 111b, the wiring pattern 112, the via pattern 113, and the metal pattern 114 may be substantially coplanar with each other, but the present disclosure is not limited thereto. A portion of each of the wiring pattern 112, the via pattern 113, and the metal pattern 114 may be removed, whereby one surface of each of the wiring pattern 112, the via pattern 113, and the metal pattern 114 may be recessed relatively inward.

The above-described printed circuit board 100B according to an example may be manufactured through a series of processes, and other descriptions may be the same as those described above. The core layer 101, the first insulating material 111a, and the second insulating material 111b may be a first insulating layer 101, a second insulating layer 111a, and a third insulating layer 111b, respectively. For example, a process may not be limited to the term “core.”

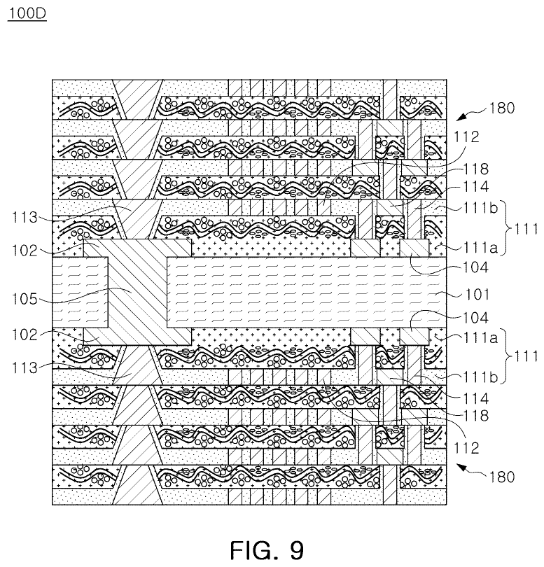

FIG. 9 is a schematic cross-sectional view of a modification of the printed circuit board of FIG. 6.

Referring to the drawings, a printed circuit board 100D according to a modification may include a core layer 101, a first pad pattern 102 disposed on each of one surface and the other surface of the core layer 101 opposing each other, a second pad pattern 104 disposed on each of the one surface and the other surface of the core layer 101 opposing each other, a through-via 105 passing through the core layer 101, the through-via 105 connecting the first pad patterns 102, respectively disposed on the one surface and the other surface of the core layer 101, to each other, and a plurality of build-up layers 180 respectively disposed on the one surface and the other surface of the core layer 101. In this case, the plurality of build-up layers 180 may include an insulating layer 111 including first and second insulating materials 111a and 111b described in connection with the above-described printed circuit board 100B according to another example, a wiring pattern 112, a via pattern 113, and a metal pattern 114. In addition, the plurality of build-up layers 180 may further include a third pad pattern 118 that is on a level substantially the same as that of the wiring pattern 112. On the one surface of the core layer 101 or the other surface of the core layer 101, the via patterns 113 respectively included in two build-up layers 150 adjacent to each other in a thickness direction, among the plurality of build-up layers 180, may be directly connected to each other. For example, a pad or land may be omitted therebetween. On the one surface of the core layer 101 or the other surface of the core layer 101, in two build-up layers 150 adjacent to each other in a thickness direction, among the plurality of build-up layers 180. The metal pattern 114 and the third pad pattern 118 may be connected to each other. Components on both sides of the core layer 101 may not need to be symmetrical to each other. For example, the plurality of build-up layers 180 may also have the same design region or different design regions. The above-described core wiring patterns 103 may be further disposed on the one surface and the other surface of the core layer 101, respectively, as necessary. The core wiring patterns 103 may have the same design region or different design regions.

As described, the printed circuit board 100D according to a modification may be a multilayer core substrate including the plurality of build-up layers 180 formed on both sides of the core layer 101. Accordingly, the printed circuit board 100D according to a modification may be easily applied to a large-area package substrate or the like. The plurality of build-up layers 180 may also be formed only on the one surface or the other surface of the core layer 101, as necessary. In this case, the printed circuit board 100D according to a modification may be easily applied to an interposer substrate or the like.

A thickness of the core layer 101 may be greater than that of each of the plurality of build-up layers 180. For example, the thickness of the core layer 101 may be greater than that of the insulating layer 111 of each of the plurality of build-up layers 180. For example, the thickness of the core layer 101 may be greater than that of each of the first and second insulating materials 111a and 111b, included in the insulating layer 111 of each of the plurality of build-up layers 180. For example, the core layer 101 may be a CCL, an unclad CCL, or the like, but the present disclosure is not limited thereto. The core layer 101 may include other insulating materials. The core layer 101 may include an inorganic insulating material such as glass, silicon, or ceramic, as necessary. In addition, the core layer 101 may include a metal core.

The through-via 105 may include a metal. The metal may include copper (Cu), aluminum (Al), silver (Ag), tin (Sn), gold (Au), nickel (Ni), lead (Pb), titanium (Ti), and/or alloys thereof. For example, the through-via 105 may include chemical copper, formed using electroless plating, as a seed layer, and may include electrolytic copper, formed using electrolytic plating based thereon, as a pattern plating layer. However, the present disclosure is not limited thereto, and the through-via 105 may include a titanium (Ti) layer and a copper (Cu) layer, formed using sputtering, as a seed layer. The through-via 105 may perform various functions depending on a design thereof. For example, the through-via 105 may include a signal transmission via, a power transmission via, a ground transmission via, or the like. The through-via 105 may have a cylindrical shape, but the present disclosure is not limited thereto. The through-via 105 may have an hourglass shape or the like. The through-via 105 may have a fill-plated via structure, but the present disclosure is not limited thereto. The through-via 105 may have a via structure filled with a filler after being conformally plated.

The third pad pattern 118 may include a metal. The metal may include copper (Cu), aluminum (Al), silver (Ag), tin (Sn), gold (Au), nickel (Ni), lead (Pb), titanium (Ti), and/or alloys thereof. For example, the third pad pattern 118 may include chemical copper, formed using electroless plating, as a seed layer, and may include a titanium (Ti) layer and a copper (Cu) layer, formed using sputtering, as a seed layer. In addition, the third pad pattern 118 may include electrolytic copper, formed using electrolytic plating based on the seed layer, as a pattern plating layer. The third pad pattern 118 may perform various functions depending on a design thereof. For example, the third pad pattern 118 may include a power transmission pad or the like.

Other descriptions may be substantially the same as those described in connection with the above-described printed circuit board 100A according to an example and the example of manufacturing the same and the above-described printed circuit board 100B according to another example and the example of manufacturing the same.

As used herein, the terms “cover,” “to cover,” and “covering” may include entirely covering as well as at least partially covering and may include directly covering as well as indirectly covering. In addition, the terms “fill,” “to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is buried. For example, an opening, exposing a pad, may be exposing the pad from a resist layer, and a surface treatment layer may be further disposed on the exposed pad.

As used herein, being disposed in an opening may include not only a case in which an object is completely disposed in the opening, but also a case in which a portion of an object protrudes upwardly or downwardly in cross-section. For example, in plan view, a case in which an object is disposed in the opening may be determined in a broader sense.

As used herein, a process error or a positional deviation occurring in a manufacturing process, an error in measurement, and the like may be included. For example, “substantially coplanar” may include not only “completely coplanar,” but also “approximately coplanar.” In addition, “being disposed on substantially the same level” may include not only “being disposed on completely the same level,” but also “being disposed on approximately the same level.” In addition, “having a substantially specific shape” may include not only “having a completely specific shape,” but also “having an approximately specific shape.” In addition, the same insulating material may mean not only the exact same insulating material, but also the same type of insulating material. Thus, compositions of insulating materials may be substantially the same, but specific composition ratios thereof may slightly vary.

As used herein, “in cross-section” may refer to a cross-sectional shape of an object when the object is vertically cut, or a cross-sectional shape of the object when the object is viewed from a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, a thickness, a width, a length, a depth, a line width, a space, a pitch, and the like may be measured using a scanning microscope or an optical microscope based on a cross-section obtained by polishing or cutting a printed circuit board. The cross-section may be a vertical cross-section or a horizontal cross-section, and each value may be measured based on the required cross-section. For example, a width of an upper end and/or lower end of a via may be measured in cross-section taken along a central axis of the via. In this case, when a component does not have a predetermined value, the value may be determined as an average value of values measured at arbitrary five points.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
an insulating layer including a first insulating material having a first opening, and a second insulating material laminated on one surface of the first insulating material, the second insulating material filling at least a portion of the first opening, the second insulating material including a material different from that of the first insulating material;
a wiring pattern disposed on the one surface of the first insulating material, the wiring pattern embedded in the second insulating material such that one surface thereof is exposed from one surface of the second insulating material; and
a via pattern spaced apart from the first insulating material in the first opening, the via pattern embedded in the second insulating material such that one surface thereof is exposed from the one surface of the second insulating material.

2. The printed circuit board of claim 1, wherein one surface of each of the wiring pattern and the via pattern is substantially coplanar with the one surface of the second insulating material or is recessed from the one surface of the second insulating material.

3. The printed circuit board of claim 1, wherein a thickness of the first insulating material is greater than that of the second insulating material.

4. The printed circuit board of claim 1, wherein
the first insulating material includes an insulating resin, an inorganic filler, and a glass fiber,
the second insulating material includes an insulating resin and an inorganic filler, and
the second insulating material does not include a glass fiber.

5. The printed circuit board of claim 4, wherein
the first insulating material includes a prepreg, and
the second insulating material includes an Ajinomoto build-up film (ABF).

6. The printed circuit board of claim 1, further comprising:
a core layer,
wherein each of the insulating layer, the wiring pattern, and the via pattern is disposed on at least one surface of the core layer,
a first pad pattern, having at least a portion covered with the first insulating material, the first pad pattern and at least another portion exposed from the first insulating material through the first opening, is further disposed on the at least one surface of the core layer, and
the via pattern is connected to at least another exposed portion of the first pad pattern.

7. The printed circuit board of claim 6, wherein a thickness of the core layer is greater than that of each of the first and second insulating materials.

8. The printed circuit board of claim 7, wherein the core layer includes a copper clad laminate (CCL) or an unclad CCL.

9. The printed circuit board of claim 6, wherein
a core wiring pattern, which is embedded in the first insulating material is further disposed on the at least one surface of the core layer, and
the wiring pattern is disposed at a density higher than that of the core wiring pattern.

10. The printed circuit board of claim 6, wherein
the first insulating material further has a second opening,
the second insulating material further fills at least a portion of the second opening,
a metal pattern spaced apart from the first insulating material in the second opening, the metal pattern having one surface exposed from the one surface of the second insulating material, is further embedded in the second insulating material,
a second pad pattern, having at least a portion covered with the first insulating material and at least another portion exposed from the first insulating material through the second opening, is further disposed on the at least one surface of the core layer, and
the metal pattern is connected to the exposed at least another portion of the second pad pattern.

11. The printed circuit board of claim 10, wherein
a thickness of the metal pattern is greater than that of the wiring pattern,
the wiring pattern includes a signal transmission line, and
the metal pattern includes a power transmission line.

12. The printed circuit board of claim 6, wherein
the first pad pattern and a plurality of build-up layers are disposed on each of the one surface and another surface of the core layer, opposing each other,
the first pad patterns, respectively disposed on the one surface and the other surface of the core layer, are connected to each other through a through-via passing through the core layer,
each of the plurality of build-up layers includes the insulating layer, the wiring pattern, and the via pattern,
via patterns respectively included in two build-up layers adjacent to each other in a thickness direction, among the plurality of build-up layers, are directly connected to each other, on either the one surface of the core layer or the other surface of the core layer.

13. A printed circuit board comprising:
a first insulating layer;
a first pad pattern disposed on the first insulating layer;
a second insulating layer disposed on the first insulating layer, the second insulating layer covering at least a portion of the first pad pattern, the second insulating layer having a first opening exposing at least another portion of the first pad pattern;
a wiring pattern disposed on the second insulating layer;
a third insulating layer disposed on the second insulating layer, the third insulating layer covering at least a portion of the wiring pattern, the third insulating layer filling at least a portion of the first opening; and
a via pattern connected to at least an open portion of the first pad pattern, the via pattern spaced apart from the second insulating layer in the first opening, the via pattern having a side surface having at least a portion covered by the third insulating layer,
wherein each of an upper surface of the wiring pattern and an upper surface of the via pattern is exposed from an upper surface of the third insulating layer, and
the second and third insulating layers include different insulating materials.

14. The printed circuit board of claim 13, wherein
a thickness of the second insulating layer is greater than that of the third insulating layer,
the second insulating layer includes an insulating resin, an inorganic filler, and a glass fiber,
the third insulating layer includes an insulating resin and an inorganic filler, and
the third insulating layer does not include a glass fiber.

15. The printed circuit board of claim 13, wherein
a second pad pattern having at least a portion, covered by the second insulating layer, is further disposed on the first insulating layer,
the second insulating layer further has a second opening exposing at least another portion of the second pad pattern,
the third insulating layer further fills at least a portion of the second opening,
a metal pattern connected to at least another exposed portion of the second pad pattern, the metal pattern spaced apart from the second insulating layer in the second opening, the metal pattern having a side surface having at least a portion, covered by the third insulating layer, is further disposed on the second pad pattern, and
an upper surface of the metal pattern is exposed from the upper surface of the third insulating layer.

16. The printed circuit board of claim 15, wherein
a thickness of the metal pattern is greater than that of the wiring pattern,
the wiring pattern includes a signal transmission line, and
the metal pattern includes a power transmission line.

17. The printed circuit board of claim 13,
wherein the via pattern has a tapered shape in cross-section, with an upper end having a width greater than a width of a lower end thereof.

18. The printed circuit board of claim 13,
wherein the via pattern has a landless via structure.
